(19) United States
(12) Patent Application Publication
(10) Pub. No.: US 2007/0284723 A1
(43) Pub. Date: Dec. 13, 2007

(54) PACKAGED INTEGRATED CIRCUIT DEVICE

(76) Inventor: Jae June Kim, Seongnam-si (KR)

Correspondence Address: IPLA P.A., 3580 WILSHIRE BLVD., 17TH FLOOR, LOS ANGELES, CA, 90010, US

(21) Appl. No.: 11/420,185

(22) Filed: May 24, 2006

(51) Int. Cl. H01L 23/52

(52) U.S. Cl. 257/692

(57) ABSTRACT

A packaged integrated circuit device is disclosed, in which there are provided at least one pad formed at an active surface and a conductive line which is connected with a non-active surface along a lateral surface, so that a connection between the pad and the non-active surface is performed through a redistribution substrate. In the packaged integrated circuit device, an assembling work using a whole semiconductor substrate and productivity are enhanced. A foreign substance is prevented from being inputted into a sensor part formed on an active surface of a semiconductor substrate, and a small size package product can be possible. It is well applicable to the semiconductor products, which are designed to operate in accordance with external physical signals.

### TECHNICAL FIELD

The present invention relates to a packaged integrated circuit device, and in particular to a packaged integrated circuit device in which there are provided at least one pad formed at an active surface and a conductive line which is connected with a non-active surface along a lateral surface, so that a connection between the pad and the non-active surface (or lateral surface or opposite surface of the active surface) is performed through a redistribution substrate.

### BACKGROUND ART

Generally, an integrated circuit (IC) is referred to a circuit in which an electronic circuit device like a transistor, a diode, a resistor, a condenser, etc. is intensively integrated on a semiconductor substrate for thereby forming a packaged structure. Here, a packaging is referred to a process in which each chip manufactured through a wafer process is electrically connected for the use as an electronic part, and the connected electronic parts are sealingly packaged for protecting them from an external impact.

In the conventional packaged integrated circuit device, a chip, which is conventionally manufactured using a wafer, is bonded to a chip support paddle, and an electric connection terminal of an inner side of a chip and a lead frame, which is an electric connection terminal of a package, are connected with each other using an electric conductive wire. In addition, the packaged integrated circuit device is sealingly molded using a certain molding material like plastic or ceramic so as to protect a packaged inner chip and an electric conductive wire.

As multimedia and information communication industries are recently advanced, a demand for an intensively integrated and high performance semiconductor chip continuously increases. As the use of connection terminals increases, and a chip size decreases, there are many constraints due to the physical and electrical characteristics of a package rather than a manufacture process of a semiconductor chip. So, the package has been preferably manufactured through a method in which the distance between an electric connection terminal of an inside of a chip and a lead frame, which is an electric connection terminal of a package, is narrowed.

In addition, the use of a ball grid array (BGA) package, which is a ball type different from a conventional lead type, has increased. This type of package is developed and became a chip scale package (CSP) type in which a package size is similar with the size of a mounted chip.

In a new technology, an active surface and a non-active surface of a semiconductor substrate are connected with each other through a via hole which passes through a semiconductor substrate.

A Korean patent laid-open No. 2001-0001159 discloses a technology for electrically connecting an active surface and a non-active surface of a semiconductor substrate using a via hole which passes through a semiconductor substrate.

FIG. 1 is a view illustrating a structure of a conventional chip scale package using a via hole.

As shown therein, in a conventional chip size package using a via hole, a chip scale package comprises a semiconductor chip 110 which has an active surface 114 and an opposite non-active surface 116 (lower surface in the laid-open document), with a plurality of bonding pads 112 being formed on the active surface 114; a conductive line 120 which electrically connects the active surface 114 and the non-active surface 116 and is formed along a lateral surface of the semiconductor chip 110; a metallic wire 140 which is electrically connected with a certain bonding pad 112 through the conductive line 120 and forms a ball pad corresponding to a bonding pad 112 at the non-active surface 116; a packaging member 130 for packaging the bonding pads 112, the metallic wire 140 and the conductive line 120, and a solder ball 150 which is formed on each ball pad. In the structure of the above chip scale package, the conductive line 120 is formed using a via hole which is formed along a scribing line at a wafer level in which the semiconductor lines are provided.

However, in the conventional chip scale package using a via hole, since a bonding pad and a conductive line are connected using a bonding wire, and a metallic wire is formed on an active surface of a semiconductor chip, there are constraints during the manufacture of intensive semiconductor devices. In particular, many constraints are present in the availability of designs when a photo sensor package like a charge coupled device (CCD), a complementary metal oxide semiconductor (CMOS), etc. is manufactured.

### DISCLOSURE OF THE INVENTION

Accordingly, it is an object of the present invention to provide a packaged integrated circuit device which overcomes the problems encountered in the conventional art.

It is another object of the present invention to provide a packaged integrated circuit device in which a pad formed on an active surface of a semiconductor substrate and a conductive line connected with a non-active surface are electrically connected using a separate redistribution substrate.

It is further another object of the present invention to provide a packaged integrated circuit device which is capable of preventing a foreign substance from being inputted into a sensor part formed on an active surface of a semiconductor substrate using a redistribution substrate which has dam protrusions.

To achieve the above objects, there is provided a packaged integrated circuit device which comprises a semiconductor substrate which has at least one pad formed on an active surface, with a conductive line connected with a non-active surface along a lateral surface being formed and corresponded to the pad; and a redistribution substrate which is engaged to the semiconductor substrate for electrically connecting the pad and the conductive line.

To achieve the above objects, there is further provided a packaged integrated circuit device which comprises a semiconductor substrate which includes an active surface and a non-active surface, which is an opposite side of the active surface, with a photo sensor and at least one pad being formed on the active surface, and with a conductive line, which is connected with the non-active surface along a lateral surface, being formed and corresponded to the pad; and a redistribution substrate which is engaged to the semiconductor substrate for electrically connecting the pad and the conductive line.

Here, the conductive line is formed using a hole, which passes through the semiconductor substrate, or part of the hole, and the hole is formed by either a drill method or an etching method.

The conductive line is formed by including at least one among W, Ti, Al, Zr, Cr, Cu, Au, Ag, Pb, ITO (Indium tin Oxide) and Ni.

The semiconductor substrate includes a terminal which is formed on a non-active surface and is electrically connected with an electric circuit of an external PCB (Printed Circuit Board), and the conductive line is electrically connected with the terminal, and the terminal is a solder ball which connects metals or the terminal is a solder pad which connects metals.

The semiconductor substrate includes a terminal which is formed on a lateral surface and is electrically connected with an external PCB, and the conductive line is electrically connected with the terminal, and the terminal is soldered to a pad of the PCB.

There is further provided a metallic wire which is pattern-plated between the conductive line and the terminal at a seed layer which is formed of at least one material among Cr, Ti and TiW, with the pattern-plating being performed in one sequence among a sequence of Ti, Cu, Ni and Au, a sequence of Cr, Cu, Ni and Au and a sequence of TiW and Ni.

The metallic wire is patterned as a photo resist is coated and patterned and is sealed by a sealing member in a state that the terminal is mounted.

A portion between the semiconductor substrate and the conductive line is molded using a thermosetting polymer compound (for example, epoxy).

The redistribution substrate has pattern protrusions each contacting with the pad and the conductive line, respectively, with the pattern protrusions being formed in pairs, and the pattern protrusions formed in pairs are coated with a first metallic layer, and the pad is formed of a metallic layer which contains Al as a major material.

The first metallic layer is coated in one material sequence among a sequence of Cr, Cu and Ti, a sequence of Ti, Cu and Ni, a sequence of Cr, Cu and Ni and a sequence of Ti, W and Ni, and each material is coated with a thickness of 50 Å through 25 um.

The first metallic layer is coated by one method among a deposition method, a sputtering method, a plating method, a non-electrolysis method, a screen printing method and an ink printing method.

The redistribution substrate includes a dam protrusion for preventing a foreign substance from inputting into a photo sensor.

The pattern protrusion and dam protrusion are patterned with a polymer compound (for example, polyimide), respectively.

An upper side of the pad contacting with the pattern protrusion, the conductive line and a portion contacting with the dam protrusion are coated with a second metallic layer, and the second metallic layer is coated with one among Au, Ni, Al and Cu with a thickness of 100 Å through 5 um.

The redistribution substrate is a glass substrate which contains an indium tin oxide (ITO) material.

A portion between the semiconductor substrate and the redistribution substrate is coated with either an anisotropy conductive epoxy or a nano interconnect paste.

### BRIEF DESCRIPTION OF THE DRAWINGS

The present invention will become better understood with reference to the accompanying drawings which are given only by way of illustration and thus are not limitative of the present invention, wherein;

FIG. 1 is a view illustrating a structure of a conventional chip scale package using a via hole;

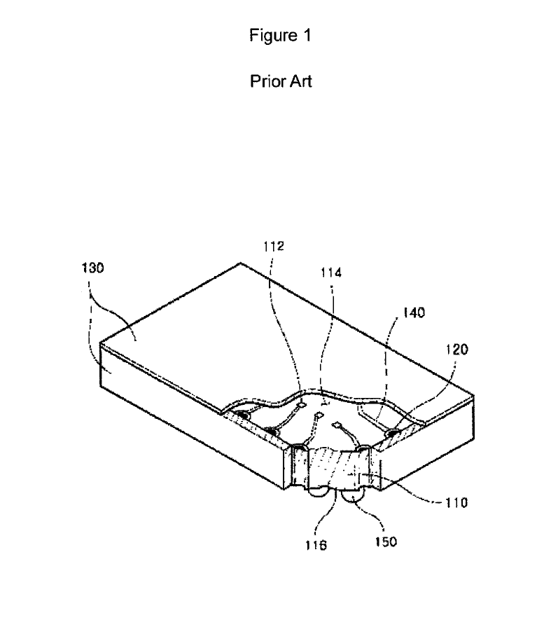

FIG. 2 is a view illustrating a packaged integrated circuit device according to an embodiment of the present invention; and

FIG. 3 is a view illustrating a packaged integrated circuit device according to another embodiment of the present invention.

### MODES FOR CARRYING OUT THE INVENTION

The preferred embodiments of the present invention will be described with reference to the accompanying drawings.

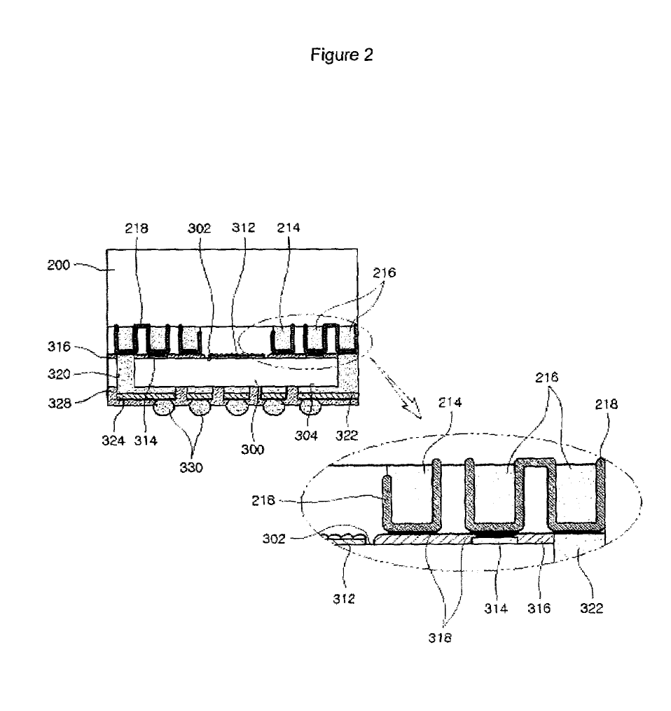

FIG. 2 is a view illustrating a packaged integrated circuit device according to an embodiment of the present invention. As shown therein, a packaged integrated circuit device according to an embodiment of the present invention comprises a semiconductor substrate 300 and a redistribution substrate 200.

Here, the semiconductor substrate 300 is a thin substrate with a thickness of 50 through 150 um and is made of a single crystal silicon and includes an active surface and a non-active surface (lateral surface or opposite surface of an active surface). A plurality of pads 314, which operate as electric connection terminals, are formed on the active surface 302 of the semiconductor substrate 300. A plurality of conductive lines 322, which are connected with the non-active surface 304, are formed along the lateral surface, with the conductive lines 322 corresponding to the pads 314.

Here, the pads 314 are preferably made of a material which contains Al (aluminum). For example, the pads 314 may be made of only Al or may be made of an alloy material of Al and Cu (copper).

The conductive line 322 is electrically connected with an external leading terminal 330 formed on a non-active surface (lateral surface or opposite surface of the active surface) 304 of the semiconductor substrate 300, namely, is electrically connected with a terminal which is connected with an external electric circuit like a printed circuit board (PCB). Here, the terminal 330 may be a solder ball, a solder pad or a contact pad which connects metals.

The conductive line 322 may be formed of a metal or a non-metallic material having a high conductivity. For example, the conductive line 322 may be made of a material which contains W, Ti, Al, Zr, Cr, Cu, Ni, Au, Ag, Pb and Indium tin oxide (ITO). Preferably, the conductive line 322 may be coated in a sequence of Cr, Cu and Ni.

The conductive line 322 may be soldered with the PCB using a via hole 320 or part of the via hole 320, which passes through the semiconductor substrate 300, based on a soldering accuracy of the soldering technology.

Here, the via hole 320 may be formed by a drilling method using a laser drill or a mechanical drill or an etching method such as a dry etching method using plasma or a reactive ion etching method.

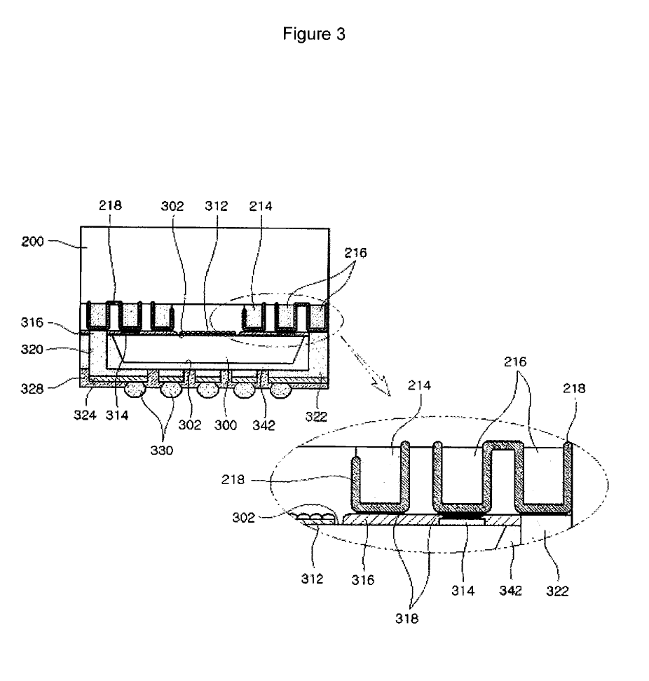

In the case that the via hole 320 is formed using the etching method, it is preferred to mold a portion between the semiconductor substrate 300 and the conductive line 322 using a cross-linkable thermosetting polymer compound 342 such as epoxy. FIG. 3 is a view illustrating a packaged integrated circuit device according to another embodiment of the present invention. As shown therein, the packaged integrated circuit device according to another embodiment of the present invention has the same structure as the packaged integrated circuit device according to an embodiment of the present invention except for the construction that it is molded with the epoxy 342.

The connection between the conductive line 322 and the terminal 330 may be performed using a metal, which has a strong bonding characteristic, such as silicon and Cr, Ti, W, etc. The connection between the same may be performed in a metal layer structure formed of a composite construction of other metals. For example, Ni may be used for a Tin diffusion barrier, and an Au layer may be used for a solder wetting operation.

In the case that a connection between the conductive line 322 and the terminal 330 is performed using a composite metallic layer, the composite metallic layer may be formed of an adhesion layer formed of Cr, Ti or TiW or a seed layer. The composite metallic layer may be a metallic wire 423 which is formed in such a manner that the seed layer is pattern-plated using a metal having an excellent electric conductivity and thermal conductivity.

The metallic wire 423 may be pattern-plated in a sequence of Ti, Cu, Ni, and Au or in a sequence of Cr, Cu, Ni, Au or in a sequence of TiW and Ni.

When a photo resist is used when the metallic wire 324 is formed, the photo resist may be used as a sealing member after the terminal 330 is mounted. For example, the metallic wire 324 may be coated with a photo resist and may be patterned together with the photo resist which is patterned by a photo resister, a mask or a laser. Then the metallic wire is preferably sealed using a sealing member such as a photo solder resister (PSR) 328 in a state that a terminal 330 such as a solder ball is mounted.

The redistribution substrate 200 electrically connects the pads 314 formed on the semiconductor substrate 300 and the conductive line 322. The redistribution substrate 200 is one of the most important features of the present invention.

In other words, in the packaged integrated circuit device according to an embodiment of the present invention, the electric connection between the pads 314 formed on the active surface 302 of the semiconductor substrate 300 and the conductive line 322 (connected with the terminal mounted in the side of the non-active surface of the semiconductor substrate) is performed using a redistribution substrate 200 which is separately provided from the semiconductor substrate 300, as compared to the conventional art in which the above connection is performed using a wire formed on the active surface 302 of the semiconductor substrate 300 or a wire bonding method.

Here, the redistribution substrate 200 may be preferably formed of a substrate made of a material having an excellent light transitivity such as glass, quartz, etc. or may be preferably formed of a substrate made of an indium tin oxide (ITO). The material of the redistribution substrate 200 is not limited to the above-disclosed materials. Namely, the redistribution substrate 200 may be formed of a substrate made of ceramic or semiconductor which can substantially perform a function of electrically connecting the pad 314 formed on the semiconductor substrate 300 and the conductive line 322.

The redistribution substrate 200 comprises pattern protrusions 216, which are formed on one surface of the same and contact with the pads 314 and the conductive line 322, for electrically connecting the pads 314 of the semiconductor substrate 300 and the conductive line 322. The pattern protrusions 216 are preferably coated with a first metallic layer 218 and are preferably engaged in a state that the pattern protrusions 216 are aligned with respect to the semiconductor substrate 300.

Namely, the pads 314 and the conductive line 322 are electrically connected through the first metallic layer 218 coated on the pattern protrusions 216.

The first metallic layer 218 is coated in a sequence of Cr, Cu, and Ti or in a sequence of Ti, Cu, and Ni or in a sequence of Cr, Cu and Ni or in a sequence of Ti, W, Ni and Au.

Here, each metallic material may be coated with a thickness of 50 Å through 2 um. Preferably in a sequence of the coating, a second metallic material may be coated with a thickness of 100 Å through 5 um, and a third metallic material may be coated with a thickness of 100 Å through 20 um.

The coating method of the first metallic layer 218 may be performed by a deposition method, a sputtering method, a plating method, a non-electrolysis plating method, a screen printing method or an ink printing method.

The packaged integrated circuit device according to an embodiment of the present invention may be a photo sensor package which comprises a light receiving unit 312 which is formed of an image array and a micro lens.

Here, the light receiving unit 312 is formed on the active surface 302 of the semiconductor substrate 300, and the redistribution substrate 200 may further comprise dam protrusions 214 for preventing a foreign substance from inputting into the light receiving unit 312.

The pattern protrusions 216 and the dam protrusions 214 may be formed in such a manner that an organic polymer compound such as polyimide is patterned.

The active surface 302 of the semiconductor substrate 300 is coated with a passivation film 316 which is formed of SiOₓ or SiNₓ. Here, the passivation film 316 is preferably coated so that the light receiving unit 312, the pads 314 and the conductive line 322 are exposed to the outside and normally operate.

In a state that the semiconductor substrate 300 and the redistribution substrate 200 are aligned and engaged, the second metallic layer 318 may be coated on the upper sides of the pads contacting with the pattern protrusions 216, the conductive line 322 and the passivation film 316 contacting with the dam protrusions 214.

Here, the second metallic layer 318 may be formed of the same material as the first metallic layer 218 or a combination of other metallic materials. The second metallic layer 318 is preferably coated with Au, Ni, Al or Cu and has a thickness of 1 through 3 um.

More preferably, the metallic layer, which is coated with Au, Ni, Al or Cu, may be further coated with a certain metal which has a strong oxidation resistance force like Au or which forms a conductive oxide film such as Sn with a thickness of 100 Å through 5 um.

As described above, the packaged integrated circuit device according to the present invention has the following advantages.

First, the pad formed on the active surface of the semiconductor substrate and the conductive line connected with the non-active surface are electrically connected using a redistribution substrate, so that the availability of the design when the integrated circuit device is designed, and the productivity are enhanced. A compact size package may be manufactured. In particular, the present invention may be well applicable to the semiconductor products which operate by external physical signals.

Second, it is possible to prevent a foreign substance from inputting into a sensor part formed on an active surface of a semiconductor substrate using a redistribution substrate which has dam protrusions, so that a performance and reliability of a sensor package such as a charge coupled device (CCD) are significantly enhanced.

As the present invention may be embodied in several forms without departing from the spirit or essential characteristics thereof, it should also be understood that the above-described examples are not limited by any of the details of the foregoing description, unless otherwise specified, but rather should be construed broadly within its spirit and scope as defined in the appended claims, and therefore all changes and modifications that fall within the meets and bounds of the claims, or equivalences of such meets and bounds are therefore intended to be embraced by the appended claims.

What is claimed is:

1. A packaged integrated circuit device, comprising:
a semiconductor substrate which has at least one pad formed on an active surface, with a conductive line connected with a non-active surface along a lateral surface being formed and corresponded to the pad; and
a redistribution substrate which is engaged to the semiconductor substrate for electrically connecting the pad and the conductive line.

2. The device of claim 1, wherein said conductive line is formed using a hole, which passes through the semiconductor substrate, or part of the hole.

3. The device of claim 2, wherein said hole is formed by either a drill method or an etching method.

4. The device of claim 1, wherein said conductive line is formed by including at least one among W, Ti, Al, Zr, Cr, Cu, Au, Ag, Pb, ITO (Indium tin Oxide) and Ni.

5. The device of claim 1, wherein said semiconductor substrate includes a terminal which is formed on a non-active surface and is electrically connected with an electric circuit of an external PCB (Printed Circuit Board), and said conductive line is electrically connected with the terminal.

6. The device of claim 5, wherein said terminal is a solder ball which connects metals.

7. The device of claim 5, wherein said terminal is a solder pad which connects metals.

8. The device of claim 1, wherein said semiconductor substrate includes a terminal which is formed on a lateral surface and is electrically connected with an external PCB, and said conductive line is electrically connected with the terminal.

9. The device of claim 8, wherein said terminal is soldered to a pad of the PCB.

10. The device of claim 5, further comprising a metallic wire which is pattern-plated between the conductive line and the terminal at a seed layer which is formed of at least one material among Cr, Ti and TiW, with said pattern-plating being performed in one sequence among a sequence of Ti, Cu, Ni and Au, a sequence of Cr, Cu, Ni and Au and a sequence of TiW and Ni.

11. The device of claim 10, wherein said metallic wire is patterned as a photo resist is coated and patterned and is sealed by a sealing means in a state that the terminal is mounted.

12. The device of claim 10, wherein said metallic wire is patterned by a laser trimming method and is sealed by a sealing means in a state that the terminal is mounted.

13. The device of claim 1, wherein a portion between the semiconductor substrate and the conductive line is molded using a thermosetting polymer compound.

14. The device of claim 1, wherein said redistribution substrate has pattern protrusions each contacting with the pad and the conductive line, respectively, with the pattern protrusions being formed in pairs, and the pattern protrusions formed in pairs are coated with a first metallic layer.

15. The device of claim 14, wherein said pad is formed of a metallic layer which contains Al as a major material.

16. The device of claim 14, wherein said first metallic layer is coated in one material sequence among a sequence of Cr, Cu and Ti, a sequence of Ti, Cu and Ni, a sequence of Cr, Cu and Ni and a sequence of Ti, W and Ni, and each material is coated with a thickness of 50 Å through 25 um.

17. The device of claim 16, wherein said first metallic layer is coated by one method among a deposition method, a sputtering method, a plating method, a non-electrolysis method, a screen printing method and an ink printing method.

18. The device of claim 14, wherein said pattern protrusion is formed in such a manner that a polymer compound is patterned.

19. The device of claim 14, wherein an upper side of the pad contacting with the pattern protrusion and the conductive line are coated with a second metallic layer.

20. The device of claim 19, wherein said second metallic layer is coated with one among Au, Ni, Al and Cu with a thickness of 100 Å through 5 um.

21. The device of claim 14, wherein said redistribution substrate is a glass substrate which contains an indium tin oxide (ITO) material.

22. The device of claim 1, wherein a portion between the semiconductor substrate and the redistribution substrate is coated with either an anisotropy conductive epoxy or a nano interconnect paste.

23. A packaged integrated circuit device, comprising:
a semiconductor substrate which includes an active surface and a non-active surface, which is an opposite side of the active surface, with a photo sensor and at least one pad being formed on the active surface, and with a conductive line, which is connected with the non-active surface along a lateral surface, being formed and corresponded to the pad; and
a redistribution substrate which is engaged to the semiconductor substrate for electrically connecting the pad and the conductive line.

24. The device of claim 23, wherein said redistribution substrate has pattern protrusions each contacting with the pad and the conductive line, respectively, with the pattern protrusions being formed in pairs, and the pattern protrusions formed in pairs are coated with a first metallic layer.

25. The device of claim 23, wherein said pad is formed of a metallic layer which contains Al as a major material.

26. The device of claim 24, wherein said first metallic layer is coated in one material sequence among a sequence of Cr, Cu and Ti, a sequence of Ti, Cu and Ni, a sequence of Cr, Cu and Ni and a sequence of Ti, W and Ni, and each material is coated with a thickness of 50 Å through 25 um.

27. The device of claim 24, wherein said redistribution substrate includes a dam protrusion for preventing a foreign substance from inputting into a photo sensor.

28. The device of claim 27, wherein said pattern protrusion and dam protrusion are patterned with a polymer compound, respectively.

29. The device of claim 28, wherein an upper side of the pad contacting with the pattern protrusion, the conductive line and a portion contacting with the dam protrusion are coated with a second metallic layer.

30. The device of claim 29, wherein said second metallic layer is coated with one among Au, Ni, Al and Cu with a thickness of 100 Å through 5 um.

31. The device of claim 23, wherein said redistribution substrate is a glass substrate which contains an indium tin oxide (ITO) material.
